(19) United States
(12) Patent Application Publication
(10) Pub. No.: US 2025/0105794 A1
(43) Pub. Date: Mar. 27, 2025

(54) POWER AMPLIFICATION DEVICE

(71) Applicant: Murata Manufacturing Co., Ltd., Kyoto (JP)

(72) Inventors: Jun ENOMOTO, Kyoto (JP); Shohei IMAI, Kyoto (JP); Hideyuki SATO, Kyoto (JP)

(21) Appl. No.: 18/894,479

(22) Filed: Sep. 24, 2024

(30) Foreign Application Priority Data
Sep. 25, 2023 (JP) 2023-161493

(51) Int. Cl. H03F 1/02; H03F 3/24; H03F 3/45; H03F 3/60

(52) U.S. Cl. CPC H03F 1/0288; H03F 3/245; H03F 3/45076; H03F 3/602; H03F 3/605; H03F 2200/06; H03F 2200/192; H03F 2200/451

(57) ABSTRACT

A substrate and a chip device mounted on a main surface of the substrate are provided. The chip device is provided with a first differential amplifier including a first carrier amplifier and a second carrier amplifier, and a second differential amplifier including a first peak amplifier and a second peak amplifier. In the chip device, the first carrier amplifier and the second carrier amplifier are disposed side by side in a first direction, the first carrier amplifier and the first peak amplifier are disposed side by side in a second direction different from the first direction, the first peak amplifier and the second peak amplifier are disposed side by side in the first direction, and the second carrier amplifier and the second peak amplifier are disposed side by side in the second direction.

### CROSS REFERENCE TO RELATED APPLICATION

This application claims priority from Japanese Patent Application No. 2023-161493 filed on Sep. 25, 2023. The content of this application is incorporated herein by reference in its entirety.

### BACKGROUND ART

The present disclosure relates to a power amplification device.

A Doherty amplifier is known as a highly efficient power amplifier. The Doherty amplifier has a configuration described below in most cases. A carrier amplifier and a peak amplifier are coupled in parallel, in which the carrier amplifier operates regardless of a power level of a radio frequency input signal, and the peak amplifier turns off when the power level of the radio frequency input signal is low and turns on when the power level of the radio frequency input signal is high. In the configuration above, when the power level of a radio frequency input signal is high, the carrier amplifier operates while maintaining saturation at a saturation output power level. As a result, the Doherty amplifier may increase the efficiency as compared with a normal power amplifier. A radio frequency module is disclosed in which such Doherty amplifier is formed as a differential configuration, and an amplifier, a phase shifter, and a transformer for output matching constituting the differential Doherty amplifier are disposed on a module substrate (for example, Japanese Unexamined Patent Application Publication No. 2022-90557).

### BRIEF SUMMARY

In recent years, supporting a higher frequency and a higher output of a power amplification device has been an issue. Conditions to achieve supporting a higher frequency and a higher output of a differential Doherty amplifier include lowering impedance of a phase shifter. In order to obtain amplification characteristics, impedance of a phase shifter of one portion of a differential circuit and impedance of a phase shifter of the other portion of the differential circuit need be symmetrical.

The present disclosure realizes a power amplification device capable of supporting a higher frequency and a higher output.

A power amplification device of an aspect of the present disclosure includes a substrate and a chip device mounted on a main surface of the substrate. The chip device includes a first differential amplifier including a first carrier amplifier and a second carrier amplifier and a second differential amplifier including a first peak amplifier and a second peak amplifier. In the chip device, the first carrier amplifier and the second carrier amplifier are disposed side by side in a first direction, the first carrier amplifier and the first peak amplifier are disposed side by side in a second direction different from the first direction, the first peak amplifier and the second peak amplifier are disposed side by side in the first direction, and the second carrier amplifier and the second peak amplifier are disposed side by side in the second direction.

With the configuration above, impedance of a phase shifter provided between the first differential amplifier and the second differential amplifier may be lowered. As a result, supporting a higher frequency and a higher output of the power amplification device may be achieved. Further, impedance of a phase shifter provided between the first carrier amplifier and the first peak amplifier and impedance of the phase shifter provided between the second carrier amplifier and the second peak amplifier may be made substantially symmetrical. As a result, suitable amplification characteristics may be obtained.

According to the present disclosure, a power amplification device capable of supporting a higher frequency and a higher output may be realized.

### BRIEF DESCRIPTION OF THE DRAWINGS

FIG. 1 is a diagram illustrating an example of a circuit configuration of a power amplification device according to the present disclosure;

FIG. 2A is a plan view illustrating a conceptual layout example of constituents of the power amplification device according to Embodiment 1;

FIG. 2B is a plan view illustrating a conceptual layout example of constituents of the power amplification device according to Embodiment 1;

FIG. 3 is a plan view illustrating a conceptual layout example of constituents of a power amplification device according to a first modification of Embodiment 1;

FIG. 4A is a diagram illustrating a configuration example of a first phase shifter and a second phase shifter according to a second modification of Embodiment 1;

FIG. 4B is a diagram illustrating a configuration example of a first phase shifter and a second phase shifter according to a third modification of Embodiment 1;

FIG. 4C is a diagram illustrating a configuration example of a first phase shifter and a second phase shifter according to a fourth modification of Embodiment 1;

FIG. 4D is a diagram illustrating a configuration example of a first phase shifter and a second phase shifter according to a fifth modification of Embodiment 1;

FIG. 5 is a plan view illustrating a conceptual layout example of constituents of a power amplification device according to Embodiment 2;

FIG. 6A is a plan view illustrating a conceptual layout example of constituents of a power amplification device according to Embodiment 3;

FIG. 6B is a plan view illustrating a conceptual layout example of constituents of the power amplification device according to Embodiment 3;

FIG. 7A is a diagram illustrating a configuration example of a phase shifter according to a first modification of Embodiment 3;

FIG. 7B is a diagram illustrating a configuration example of a phase shifter according to a second modification of Embodiment 3;

FIG. 8 is a plan view illustrating a conceptual layout example of constituents of a power amplification device according to a third modification of Embodiment 3; and

FIG. 9 is a plan view illustrating a conceptual layout example of constituents of a power amplification device according to a fourth modification of Embodiment 3.

### DETAILED DESCRIPTION

Hereinafter, a power amplification device according to embodiments will be described in detail with reference to the drawings. The present disclosure is not limited to the embodiments. Each embodiment is an example, and it is needless to say that partial replacement or combination of configurations illustrated in different embodiments is possible. In Embodiment 2 and subsequent embodiments, a description of matters common to Embodiment 1 will be omitted, and only different points will be described. In particular, same and/or similar effects of same and/or similar configurations will not be described in each embodiment.

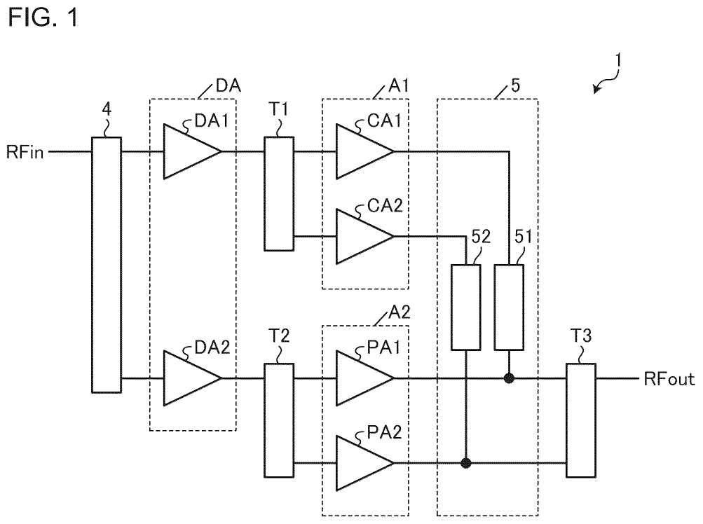

FIG. 1 is a diagram illustrating an example of a circuit configuration of a power amplification device according to the present disclosure. A power amplification device 1 amplifies a radio frequency input signal RFin and outputs a radio frequency output signal RFout. In the present disclosure, the power amplification device 1 is a Doherty type power amplifier formed as a differential configuration (hereinafter, also referred to as “differential Doherty amplifier”).

The differential Doherty amplifier includes a first carrier amplifier CA1, a second carrier amplifier CA2, a first peak amplifier PA1, a second peak amplifier PA2, a first conversion circuit T1, a second conversion circuit T2, and a third conversion circuit T3.

The first carrier amplifier CA1 and the second carrier amplifier CA2 constitute a first differential amplifier A1. The first conversion circuit T1 converts the radio frequency input signal RFin being an unbalanced input signal into a differential signal, and inputs the differential signal to the first differential amplifier A1. The first conversion circuit T1 is configured of, for example, a balun transformer.

The first peak amplifier PA1 and the second peak amplifier PA2 constitute a second differential amplifier A2. The second conversion circuit T2 converts an unbalanced input signal inputted via an input phase shifter 4 and a drive stage amplifier DA into a differential signal, and inputs the differential signal to the second differential amplifier A2. The second conversion circuit T2 is configured of, for example, a balun transformer.

The input phase shifter 4 delays a phase of the radio frequency input signal RFin by 90 degrees. The input phase shifter 4 is configured of, for example, a transmission line or a 90 degrees hybrid coupler.

The drive stage amplifier DA includes a first drive stage amplifier DA1 and a second drive stage amplifier DA2. The first drive stage amplifier DA1 amplifies the radio frequency input signal RFin being an unbalanced input signal, and inputs the amplified signal to the first conversion circuit T1. The second drive stage amplifier DA2 amplifies an unbalanced input signal obtained by delaying the radio frequency input signal RFin by 90 degrees, and inputs the amplified signal to the second conversion circuit T2.

A phase shifter 5 is provided between an output of the first differential amplifier A1 and an output of the second differential amplifier A2. The phase shifter 5 delays a phase of a differential output of the first differential amplifier A1 by 90 degrees.

The phase shifter 5 includes a first phase shifter 51 having one end coupled to an output of the first carrier amplifier CA1 and the other end coupled to an output of the first peak amplifier PA1, and a second phase shifter 52 having one end coupled to an output of the second carrier amplifier CA2 and the other end coupled to an output of the second peak amplifier PA2. The first phase shifter 51 delays an output phase of the first carrier amplifier CA1 by 90 degrees. The second phase shifter 52 delays an output phase of the second carrier amplifier CA2 by 90 degrees. The first phase shifter 51 and the second phase shifter 52 are each formed of, for example, a transmission line or an LC circuit including an inductor and a capacitor.

The differential signal outputted from a coupling point between the output of the second differential amplifier A2 and the phase shifter 5 is converted into the RFout being an unbalanced output signal by the third conversion circuit T3. The third conversion circuit T3 is configured of, for example, a balun transformer.

In the differential Doherty amplifier illustrated in FIG. 1, the first differential amplifier A1 (first carrier amplifier CA1 and second carrier amplifier CA2) operates regardless of the power level of the radio frequency input signal RFin. The second differential amplifier A2 (first peak amplifier PA1 and second peak amplifier PA2) is turned off when the power level of the radio frequency input signal RFin is low, and is turned on when the power level of the radio frequency input signal RFin is high. The first differential amplifier A1 and the second differential amplifier A2 are coupled in parallel to form the differential Doherty amplifier. In the configuration above, when the power level of the radio frequency input signal RFin is high, the first differential amplifier A1 (first carrier amplifier CA1 and second carrier amplifier CA2) operates while maintaining saturation at a saturation output power level. As a result, the differential Doherty amplifier may increase efficiency as compared with a normal differential amplifier.

### Embodiment 1

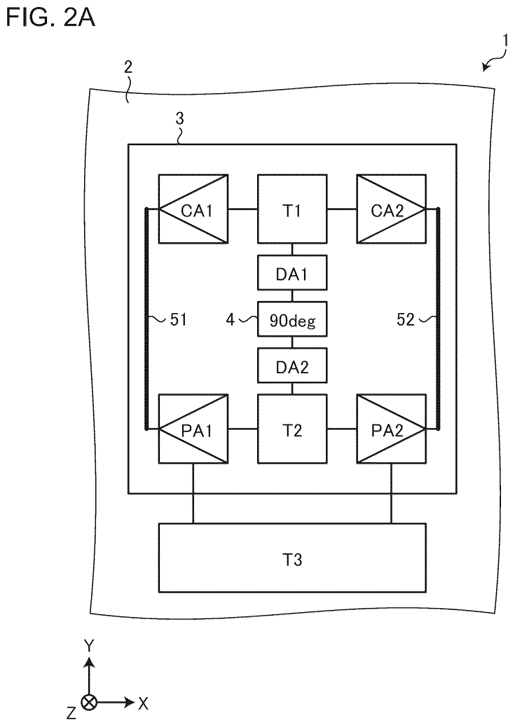

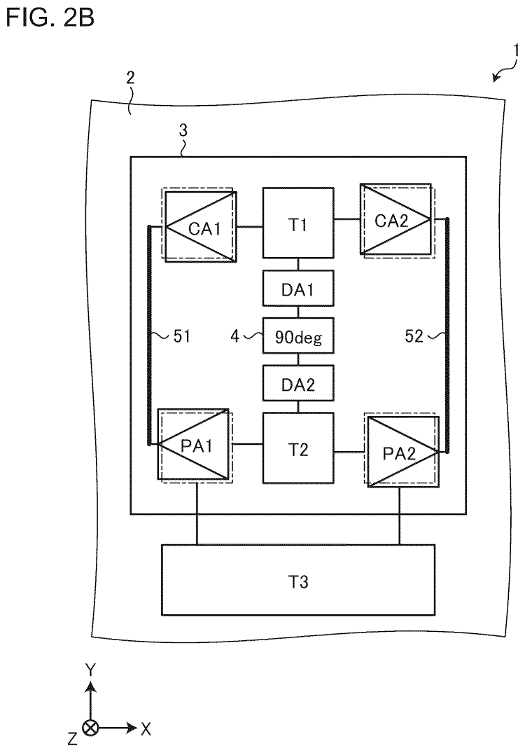

FIG. 2A and FIG. 2B are plan views each illustrating a conceptual layout example of constituents of the power amplification device according to Embodiment 1.

In FIG. 2A and FIG. 2B, as an example of the power amplification device 1, the example is illustrated in which the power amplification device 1 is mounted on a front-end module. The front-end module is a micro integrated module in which a plurality of integrated circuits and various functional components are mounted on a main surface of a substrate 2 parallel to an XY plane including an X direction and a Y direction orthogonal to the X direction illustrated in FIG. 2A and FIG. 2B. Note that, the substrate 2 includes a substrate substantially parallel to the XY plane such as a substrate having a slightly uneven surface. Examples of the substrate 2 include a ceramic laminated substrate such as a low temperature co-fired ceramics (LTCC) substrate, a resin multilayer substrate, and a film substrate. Note that the X direction and the Y direction are not necessarily orthogonal to each other. The X direction and the Y direction may be close to orthogonal (substantially orthogonal) to each other.

Main circuit blocks of the power amplification device 1 illustrated in FIG. 2A and FIG. 2B are formed on a die of a chip device 3 flip-chip mounted on the substrate 2 in a Z direction. Specifically, examples are illustrated in FIG. 2A and FIG. 2B in which at least the first carrier amplifier CA1, the second carrier amplifier CA2, the first peak amplifier PA1, the second peak amplifier PA2, the first conversion circuit T1, and the second conversion circuit T2 are formed on the die of the chip device 3.

In the present disclosure, the third conversion circuit T3 is provided on the substrate 2. Specifically, when the third conversion circuit T3 is configured of a balun transformer, winding of the balun transformer is formed of a wiring line provided on the substrate 2. This may contribute to the reduction of the chip device 3 in size. The third conversion circuit T3 may be configured of, for example, a 180 degrees hybrid coupler. This configuration may suppress a variation in output characteristics with respect to a variation in load impedance of the power amplification device 1, in comparison with a configuration in which the third conversion circuit T3 is a balun transformer.

The chip device 3 is, for example, a heterojunction bipolar transistor (HBT) device (integrated circuit, IC) including a gallium arsenide (GaAs)-based HBT, or a silicon device (integrated circuit, IC) including, for example, a silicon (Si)-based field effect transistor (FET). The first carrier amplifier CA1, the second carrier amplifier CA2, the first peak amplifier PA1, and the second peak amplifier PA2 are formed on the die of the chip device 3. The chip device 3 is bump-bonded to the main surface of the substrate 2 with, for example, a copper pillar or the like.

In the layout of the power amplification device 1 according to Embodiment 1 illustrated in FIG. 2A, the chip device 3 is configured such that the first carrier amplifier CA1 and the second carrier amplifier CA2 are disposed side by side in the X direction (first direction) and the first carrier amplifier CA1 and the first peak amplifier PA1 are disposed side by side in the Y direction (second direction). The first peak amplifier PA1 and the second peak amplifier PA2 are disposed side by side in the X direction (first direction), and the second carrier amplifier CA2 and the second peak amplifier PA2 are disposed side by side in the Y direction (second direction).

In the layout of the power amplification device 1 according to Embodiment 1 illustrated in FIG. 2B, the first carrier amplifier CA1, the second carrier amplifier CA2, the first peak amplifier PA1, and the second peak amplifier PA2 are each provided at a position shifted from each of positions of the first carrier amplifier CA1, the second carrier amplifier CA2, the first peak amplifier PA1, and the second peak amplifier PA2 indicated with a solid line in the layout illustrated in FIG. 2A (positions each illustrated with a dashed-and-dotted line in FIG. 2B).

An example is illustrated in FIG. 2A in which the disposition direction of the first carrier amplifier CA1 and the second carrier amplifier CA2 is parallel to the disposition direction of the first peak amplifier PA1 and the second peak amplifier PA2. However, as illustrated in FIG. 2B, the disposition direction of the first carrier amplifier CA1 and the second carrier amplifier CA2 and the disposition direction of the first peak amplifier PA1 and the second peak amplifier PA2 are not necessarily parallel to each other. In other words, in the present disclosure, in the layout illustrated in FIG. 2B, the first carrier amplifier CA1 and the second carrier amplifier CA2 may be considered to be disposed side by side in the X direction (first direction), as long as the first carrier amplifier CA1 is disposed such that at least part of the first carrier amplifier CA1 comes into contact with any portion of the second carrier amplifier CA2 when the first carrier amplifier CA1 is moved in the X direction (first direction). Further, the first peak amplifier PAL and the second peak amplifier PA2 may be considered to be disposed side by side in the X direction (first direction), as long as the first peak amplifier PA1 is disposed such that at least part of the first peak amplifier PA1 comes into contact with any portion of the second peak amplifier PA2 when the first peak amplifier PA1 is moved in the X direction (first direction).

Further, an example is illustrated in FIG. 2A in which the disposition direction of the first carrier amplifier CA1 and the first peak amplifier PA1 is parallel to the disposition direction of the second carrier amplifier CA2 and the second peak amplifier PA2. However, as illustrated in FIG. 2B, the disposition direction of the first carrier amplifier CA1 and the first peak amplifier PA1 and the disposition direction of the second carrier amplifier CA2 and the second peak amplifier PA2 are not necessarily parallel to each other. In other words, in the present disclosure, in the layout illustrated in FIG. 2B, the first carrier amplifier CA1 and the first peak amplifier PA1 may be considered to be disposed side by side in the Y direction (second direction), as long as the first carrier amplifier CA1 is disposed such that at least part of the first carrier amplifier CA1 comes into contact with any portion of the first peak amplifier PA1 when the first carrier amplifier CA1 is moved in the Y direction (second direction). Further, the second carrier amplifier CA2 and the second peak amplifier PA2 may be considered to be disposed side by side in the Y direction (second direction), as long as the second carrier amplifier CA2 is disposed such that at least part of the second carrier amplifier CA2 comes into contact with any portion of the second peak amplifier PA2 when the second carrier amplifier CA2 is moved in the Y direction (second direction).

The first conversion circuit T1 is provided between the first carrier amplifier CA1 and the second carrier amplifier CA2. The second conversion circuit T2 is provided between the first peak amplifier PAL and the second peak amplifier PA2.

In the layouts illustrated in FIG. 2A and FIG. 2B, each of the first phase shifter 51 and the second phase shifter 52 is a transmission line provided on the die of the chip device 3. The input phase shifter 4 is formed of a 90 degrees hybrid coupler provided on the die of the chip device 3. The input phase shifter 4 is provided between the first conversion circuit T1 and the second conversion circuit T2. The first drive stage amplifier DA1 is provided between the input phase shifter 4 and the first conversion circuit T1. The second drive stage amplifier DA2 is provided between the input phase shifter 4 and the second conversion circuit T2.

With the layout of the power amplification device 1 according to Embodiment 1 illustrated in FIG. 2A and FIG. 2B, a physical distance between the first differential amplifier A1 (first carrier amplifier CA1 and second carrier amplifier CA2) and the second differential amplifier A2 (first peak amplifier PA1 and second peak amplifier PA2) decreases, and thus the impedance of each of the first phase shifter 51 and the second phase shifter 52 may be lowered. As a result, supporting a higher frequency and a higher output of the power amplification device 1 may be achieved. Further, the disposition of the first carrier amplifier CA1 and the first peak amplifier PA1 and the disposition of the second carrier amplifier CA2 and the second peak amplifier PA2 become substantially symmetrical, and impedance of the first phase shifter 51 and impedance of the second phase shifter 52 may be made substantially symmetrical. As a result, suitable amplification characteristics may be obtained.

Hereinafter, modifications of the power amplification device according to Embodiment 1 will be described.

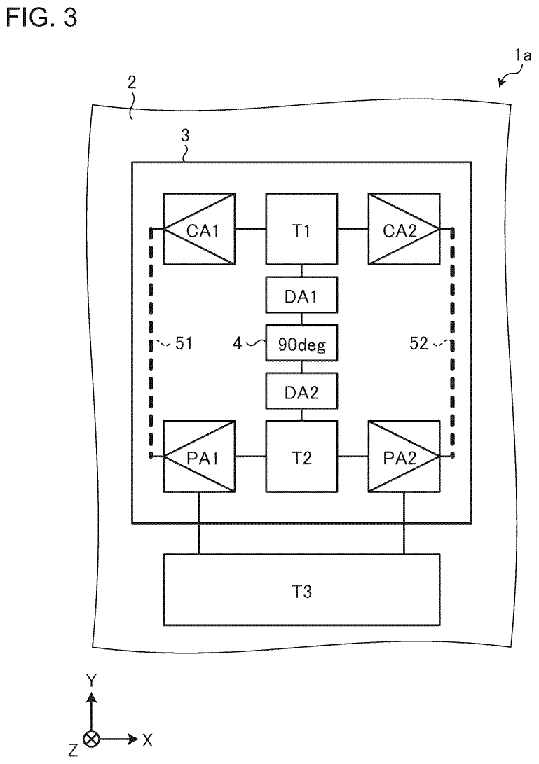

FIG. 3 is a plan view illustrating a conceptual layout example of constituents of a power amplification device according to a first modification of Embodiment 1. In the layout of a power amplification device 1a illustrated in FIG. 3, each of the first phase shifter 51 and the second phase shifter 52 is a transmission line provided on the substrate 2.

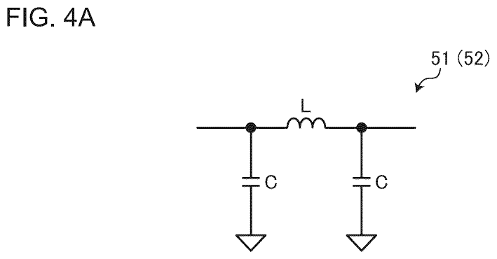

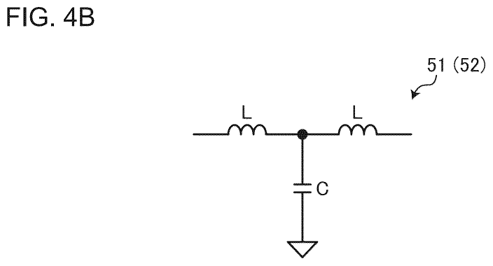

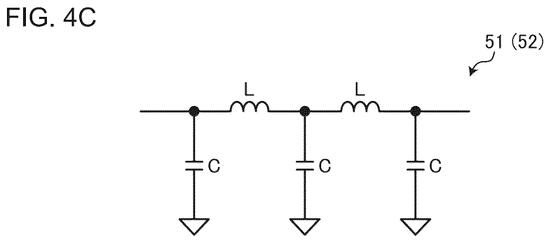

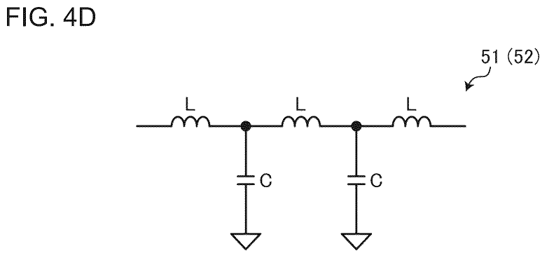

FIG. 4A is a diagram illustrating a configuration example of a first phase shifter and a second phase shifter according to a second modification of Embodiment 1. FIG. 4B is a diagram illustrating a configuration example of a first phase shifter and a second phase shifter according to a third modification of Embodiment 1. FIG. 4C is a diagram illustrating a configuration example of a first phase shifter and a second phase shifter according to a fourth modification of Embodiment 1. FIG. 4D is a diagram illustrating a configuration example of a first phase shifter and a second phase shifter according to a fifth modification of Embodiment 1.

In the configuration examples illustrated in FIG. 4A, FIG. 4B, FIG. 4C, and FIG. 4D, each of the first phase shifter 51 and the second phase shifter 52 is an LC circuit formed of an inductor L and a capacitor C. With the configurations above, reduction in size may be achieved as compared with a configuration in which each of the first phase shifter 51 and the second phase shifter is a transmission line. Further, in each configuration illustrated in FIG. 4C and FIG. 4D, by implementing the LC circuit with multiple stages, a band width may be made wider than that of each configuration illustrated in FIG. 4A and FIG. 4B.

### Embodiment 2

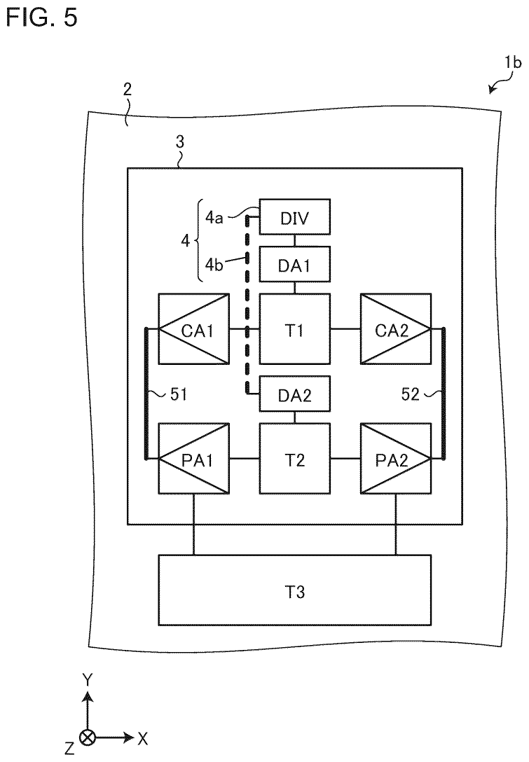

FIG. 5 is a plan view illustrating a conceptual layout example of constituents of a power amplification device according to Embodiment 2.

In the configuration of a power amplification device 1b according to Embodiment 2, the input phase shifter 4 includes a distributor 4a and a transmission line 4b. The distributor 4a is, for example, a Wilkinson type power divider formed on the die of the chip device 3. The transmission line 4b is provided on the substrate 2.

In the layout illustrated in FIG. 5, the first drive stage amplifier DA1, the first conversion circuit T1, the second drive stage amplifier DA2, and the second conversion circuit T2 are disposed in sequence in the Y direction (second direction) on the die of the chip device 3.

With the layout of the power amplification device 1b according to Embodiment 2 illustrated in FIG. 5, the physical distance between the first differential amplifier A1 (first carrier amplifier CA1 and second carrier amplifier CA2) and the second differential amplifier A2 (first peak amplifier PA1 and second peak amplifier PA2) further decreases than that of Embodiment 1, and thus the impedance of each of the first phase shifter 51 and the second phase shifter 52 may further be lowered. As a result, supporting an even higher frequency and an even higher output of the power amplification device 1b may be achieved. In the layout of the power amplification device 1b according to Embodiment 2 illustrated in FIG. 5, by making each of the first phase shifter 51 and the second phase shifter 52 an LC circuit formed of an inductor L and a capacitor C, a reduction in size and a wider band width may be achieved as in Embodiment 1.

### Embodiment 3

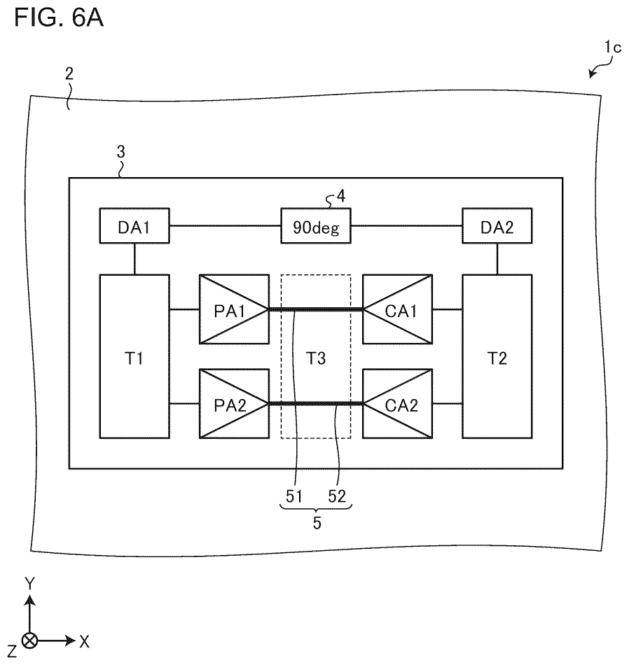

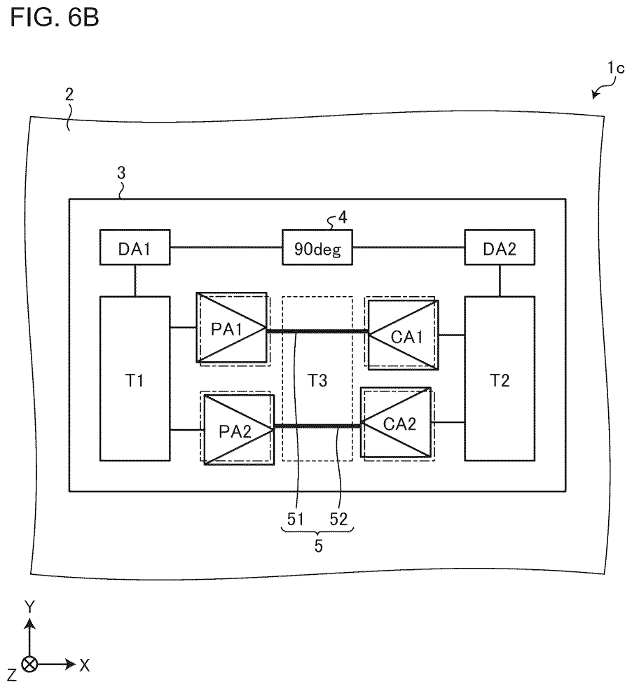

FIG. 6A and FIG. 6B are plan views each illustrating a conceptual layout example of constituents of a power amplification device according to Embodiment 3.

In the layout of a power amplification device 1c according to Embodiment 3 illustrated in FIG. 6A, the chip device 3 is configured such that the first carrier amplifier CA1 and the second carrier amplifier CA2 are disposed side by side in the Y direction (second direction) and the first carrier amplifier CA1 and the first peak amplifier PAL are disposed side by side in the X direction (first direction). The first peak amplifier PA1 and the second peak amplifier PA2 are disposed side by side in the Y direction (second direction), and the second carrier amplifier CA2 and the second peak amplifier PA2 are disposed side by side in the X direction (first direction).

In the layout of the power amplification device 1c according to Embodiment 3 illustrated in FIG. 6B, the first carrier amplifier CA1, the second carrier amplifier CA2, the first peak amplifier PA1, and the second peak amplifier PA2 are each provided at a position shifted from each of positions of the first carrier amplifier CA1, the second carrier amplifier CA2, the first peak amplifier PA1, and the second peak amplifier PA2 indicated with a solid line in the layout illustrated in FIG. 6A (positions each illustrated with a dashed-and-dotted line in FIG. 6B).

An example is illustrated in FIG. 6A in which the disposition direction of the first carrier amplifier CA1 and the second carrier amplifier CA2 is parallel to the disposition direction of the first peak amplifier PA1 and the second peak amplifier PA2. However, as illustrated in FIG. 6B, the disposition direction of the first carrier amplifier CA1 and the second carrier amplifier CA2 and the disposition direction of the first peak amplifier PA1 and the second peak amplifier PA2 are not necessarily parallel to each other. In other words, in the present disclosure, in the layout illustrated in FIG. 6B, the first carrier amplifier CA1 and the second carrier amplifier CA2 may be considered to be disposed side by side in the Y direction (second direction), as long as the first carrier amplifier CA1 is disposed such that at least part of the first carrier amplifier CA1 comes into contact with any portion of the second carrier amplifier CA2 when the first carrier amplifier CA1 is moved in the Y direction (second direction). Further, the first peak amplifier PA1 and the second peak amplifier PA2 may be considered to be disposed side by side in the Y direction (second direction), as long as the first peak amplifier PA1 is disposed such that at least part of the first peak amplifier PA1 comes into contact with any portion of the second peak amplifier PA2 when the first peak amplifier PA1 is moved in the Y direction (second direction).

Further, an example is illustrated in FIG. 6A in which the disposition direction of the first carrier amplifier CA1 and the first peak amplifier PAL is parallel to the disposition direction of the second carrier amplifier CA2 and the second peak amplifier PA2. However, as illustrated in FIG. 6B, the disposition direction of the first carrier amplifier CA1 and the first peak amplifier PA1 and the disposition direction of the second carrier amplifier CA2 and the second peak amplifier PA2 are not necessarily parallel to each other. In other words, in the present disclosure, in the layout illustrated in FIG. 6B, the first carrier amplifier CA1 and the first peak amplifier PA1 may be considered to be disposed side by side in the X direction (first direction), as long as the first carrier amplifier CA1 is disposed such that at least part of the first carrier amplifier CA1 comes into contact with any portion of the first peak amplifier PA1 when the first carrier amplifier CA1 is moved in the X direction (first direction). Further, the second carrier amplifier CA2 and the second peak amplifier PA2 may be considered to be disposed side by side in the X direction (first direction), as long as the second carrier amplifier CA2 is disposed such that at least part of the second carrier amplifier CA2 comes into contact with any portion of the second peak amplifier PA2 when the second carrier amplifier CA2 is moved in the X direction (first direction).

The first differential amplifier A1 (first carrier amplifier CA1 and second carrier amplifier CA2) and the second differential amplifier A2 (first peak amplifier PA1 and second peak amplifier PA2) are provided between the first conversion circuit T1 and the second conversion circuit T2. The input phase shifter 4 is formed of a 90 degrees hybrid coupler provided on the die of the chip device 3.

With the layout of the power amplification device 1c according to Embodiment 3 illustrated in FIG. 6A and FIG. 6B, as in Embodiment 1 and Embodiment 2, the physical distance between the first differential amplifier A1 (first carrier amplifier CA1 and second carrier amplifier CA2) and the second differential amplifier A2 (first peak amplifier PA1 and second peak amplifier PA2) decreases, and thus the impedance of each of the first phase shifter 51 and the second phase shifter 52 may be lowered. As a result, supporting a higher frequency and a higher output of the power amplification device 1c may be achieved. Further, as in Embodiment 1 and Embodiment 2, the disposition of the first carrier amplifier CA1 and the first peak amplifier PA1 and the disposition of the second carrier amplifier CA2 and the second peak amplifier PA2 become substantially symmetrical, and thus the impedance of the first phase shifter 51 and the impedance of the second phase shifter 52 may be made substantially symmetrical. As a result, suitable amplification characteristics may be obtained.

Hereinafter, modifications of the power amplification device according to Embodiment 3 will be described.

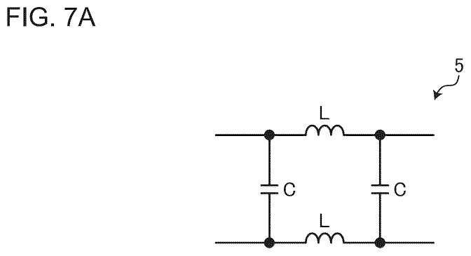

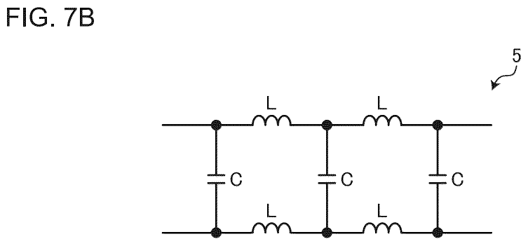

FIG. 7A is a diagram illustrating a configuration example of a phase shifter according to a first modification of Embodiment 3. FIG. 7B is a diagram illustrating a configuration example of a phase shifter according to a second modification of Embodiment 3.

In the configuration examples illustrated in FIG. 7A and FIG. 7B, the phase shifter 5 is an LC circuit formed of an inductor L and a capacitor C. With the configurations above, reduction in size may be achieved as compared with a configuration in which each of the first phase shifter 51 and the second phase shifter 52 is a transmission line. Further, in the configuration illustrated in FIG. 7B, by implementing the LC circuit with multiple stages, a band width may be made wider than that of the configuration illustrated in FIG. 7A.

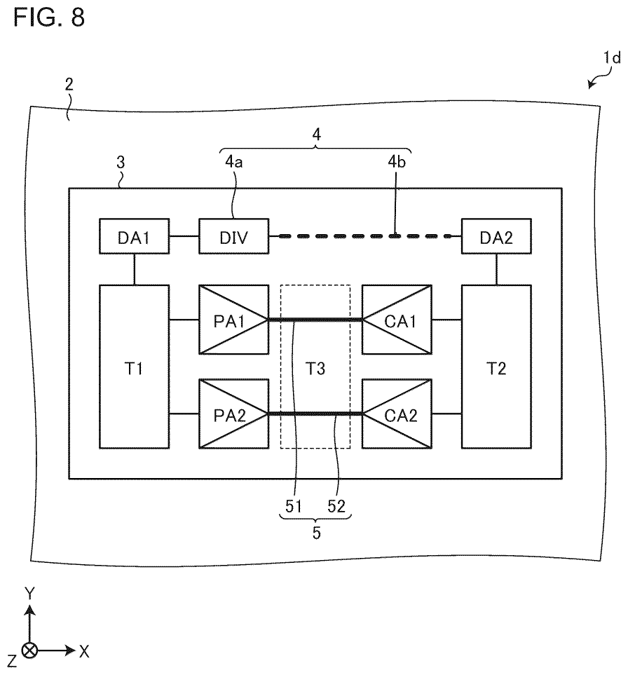

FIG. 8 is a plan view illustrating a conceptual layout example of constituents of a power amplification device according to a third modification of Embodiment 3. In the configuration of a power amplification device 1d according to the third modification of Embodiment 3, the input phase shifter 4 includes the distributor 4a and the transmission line 4b. The distributor 4a is, for example, a Wilkinson type power divider formed on the die of the chip device 3. The transmission line 4b is provided on the substrate 2.

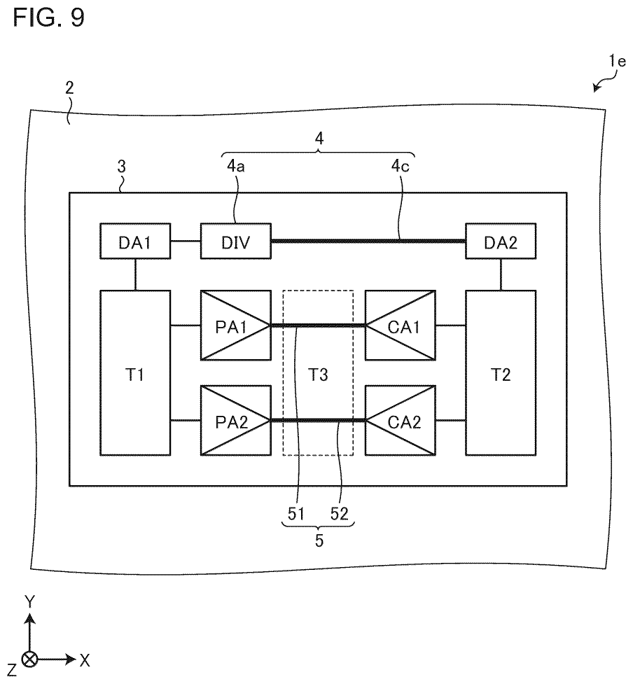

FIG. 9 is a plan view illustrating a conceptual layout example of constituents of a power amplification device according to a fourth modification of Embodiment 3. In the configuration of a power amplification device 1e according to the fourth modification of Embodiment 3, the input phase shifter 4 includes the distributor 4a and a transmission line 4c. The transmission line 4c is provided on the die of the chip device 3.

The above-described embodiments are intended to facilitate understanding of the present disclosure, and are not intended to limit the interpretation of the present disclosure. The present disclosure can be modified and/or improved without necessarily departing from the gist thereof, and equivalents thereof are also included in the present disclosure.

The present disclosure may have the following configurations as described above or instead of the above.

(1) A power amplification device of an aspect of the present disclosure comprising: a substrate; and a chip device mounted on a main surface of the substrate, wherein the chip device includes a first differential amplifier including a first carrier amplifier and a second carrier amplifier and a second differential amplifier including a first peak amplifier and a second peak amplifier, and in the chip device, the first carrier amplifier and the second carrier amplifier are disposed side by side in a first direction, the first carrier amplifier and the first peak amplifier are disposed side by side in a second direction different from the first direction, the first peak amplifier and the second peak amplifier are disposed side by side in the first direction, and the second carrier amplifier and the second peak amplifier are disposed side by side in the second direction.

With the configuration above, impedance of a phase shifter provided between the first differential amplifier and the second differential amplifier may be lowered. As a result, supporting a higher frequency and a higher output of the power amplification device may be achieved. Further, impedance of a phase shifter provided between the first carrier amplifier and the first peak amplifier and impedance of the phase shifter provided between the second carrier amplifier and the second peak amplifier may be made substantially symmetrical. As a result, suitable amplification characteristics may be obtained.

(2) The power amplification device according to (1), further comprising: a phase shifter configured to delay a phase of a differential output of the first differential amplifier by 90 degrees.

(3) The power amplification device according to (2), wherein the phase shifter includes a first phase shifter having one end coupled to an output of the first carrier amplifier and another end coupled to an output of the first peak amplifier, and a second phase shifter having one end coupled to an output of the second carrier amplifier and another end coupled to an output of the second peak amplifier.

(4) The power amplification device according to (3), wherein the first phase shifter and the second phase shifter are each formed of a transmission line provided to the chip device or the substrate.

(5) The power amplification device according to (2), wherein the phase shifter is formed of an LC circuit including an inductor and a capacitor.

With the configuration above, a reduction in size and a wider band width of a power amplification device may be achieved.

(6) The power amplification device according to any one of (2) to (5), wherein the chip device includes a first conversion circuit configured to convert an unbalanced input signal into a differential signal and input the differential signal to the first differential amplifier and a second conversion circuit configured to convert an unbalanced input signal into a differential signal and input the differential signal to the second differential amplifier, and the substrate includes a third conversion circuit configured to convert a differential signal outputted from the chip device into an unbalanced output signal.

(7) The power amplification device according to (6), wherein the first conversion circuit and the second conversion circuit are each formed of a balun transformer.

(8) The power amplification device according to (6) or (7), wherein the third conversion circuit is formed of a balun transformer.

(9) The power amplification device according to (6) or (7), wherein the third conversion circuit is formed of a hybrid coupler.

With the configuration above, a variation in output characteristics with respect to a variation in load impedance of the power amplification device may be suppressed.

(10) The power amplification device according to any one of (6) to (9), further comprising: a first drive stage amplifier configured to amplify an unbalanced input signal and input the amplified signal to the first conversion circuit; a second drive stage amplifier configured to amplify an unbalanced input signal and input the amplified signal to the second conversion circuit; and an input phase shifter configured to delay a phase of the unbalanced input signal to be inputted to the second conversion circuit by 90 degrees with respect to the unbalanced input signal to be inputted to the first conversion circuit.

(11) The power amplification device according to (10), wherein the first conversion circuit is provided between the first carrier amplifier and the second carrier amplifier, and the second conversion circuit is provided between the first peak amplifier and the second peak amplifier.

(12) The power amplification device according to (11), wherein the input phase shifter is formed of a hybrid coupler.

(13) The power amplification device according to (12), wherein the input phase shifter is provided between the first conversion circuit and the second conversion circuit, the first drive stage amplifier is provided between the input phase shifter and the first conversion circuit, and the second drive stage amplifier is provided between the input phase shifter and the second conversion circuit.

(14) The power amplification device according to (11), wherein the input phase shifter includes a transmission line provided to the substrate, and in the chip device, the first drive stage amplifier, the first conversion circuit, the second drive stage amplifier, and the second conversion circuit are disposed in sequence in the second direction.

With the configuration above, impedance of each of the first phase shifter and the second phase shifter may further be lowered. As a result, supporting an even higher frequency and an even higher output of the power amplification device may be achieved.

(15) The power amplification device according to (10) wherein the first differential amplifier and the second differential amplifier are provided between the first conversion circuit and the second conversion circuit.

With the configuration above, impedance of each of the first phase shifter and the second phase shifter may further be lowered. As a result, supporting an even higher frequency and an even higher output of the power amplification device may be achieved.

(16) The power amplification device according to (15), wherein the input phase shifter is formed of a hybrid coupler.

(17) The power amplification device according to (15), wherein the input phase shifter includes a transmission line provided to the substrate.

(18) The power amplification device according to (15), wherein the input phase shifter includes a transmission line provided to the chip device.

According to the present disclosure, a power amplification device capable of supporting a higher frequency and a higher output may be realized.

What is claimed is:

1. A power amplification device comprising:
a substrate; and
a chip device mounted on a main surface of the substrate,
wherein the chip device comprises:
a first differential amplifier comprising a first carrier amplifier and a second carrier amplifier; and
a second differential amplifier comprising a first peak amplifier and a second peak amplifier, and
wherein in the chip device:
the first carrier amplifier and the second carrier amplifier are side by side in a first direction,
the first carrier amplifier and the first peak amplifier are side by side in a second direction different from the first direction,
the first peak amplifier and the second peak amplifier are side by side in the first direction, and
the second carrier amplifier and the second peak amplifier are side by side in the second direction.

2. The power amplification device according to claim 1, further comprising:
a phase shifter configured to delay a phase of a differential output of the first differential amplifier by 90 degrees.

3. The power amplification device according to claim 2, wherein the phase shifter comprises:
a first phase shifter having a first end coupled to an output of the first carrier amplifier, and a second end coupled to an output of the first peak amplifier, and
a second phase shifter having a first end coupled to an output of the second carrier amplifier and a second end coupled to an output of the second peak amplifier.

4. The power amplification device according to claim 3, wherein the first phase shifter and the second phase shifter each comprise a transmission line of the chip device or the substrate.

5. The power amplification device according to claim 2, wherein the phase shifter comprises an LC circuit that comprises an inductor and a capacitor.

6. The power amplification device according to claim 2,
wherein the chip device comprises:
a first conversion circuit configured to convert a first unbalanced input signal into a first differential signal, and to input the first differential signal to the first differential amplifier; and
a second conversion circuit configured to convert a second unbalanced input signal into a second differential signal, and to input the second differential signal to the second differential amplifier, and
wherein the substrate comprises a third conversion circuit configured to convert a differential signal outputted from the chip device into an unbalanced output signal.

7. The power amplification device according to claim 6, wherein the first conversion circuit and the second conversion circuit each comprise a balun transformer.

8. The power amplification device according to claim 6, wherein the third conversion circuit comprises a balun transformer.

9. The power amplification device according to claim 6, wherein the third conversion circuit comprises a hybrid coupler.

10. The power amplification device according to claim 6, further comprising:
a first drive stage amplifier configured to amplify the unbalanced input signal, and to input a first amplified signal to the first conversion circuit as the first unbalanced input signal;
a second drive stage amplifier configured to amplify an unbalanced input signal, and to input a second amplified signal to the second conversion circuit as the second unbalanced input signal; and
an input phase shifter configured to delay a phase of the unbalanced input signal, such that the unbalanced input signal amplified by the first drive stage amplifier is delayed by 90 degrees with respect to the unbalanced input signal amplified by the second drive stage amplifier.

11. The power amplification device according to claim 10,
wherein the first conversion circuit is between the first carrier amplifier and the second carrier amplifier, and
wherein the second conversion circuit is between the first peak amplifier and the second peak amplifier.

12. The power amplification device according to claim 11, wherein the input phase shifter comprises a hybrid coupler.

13. The power amplification device according to claim 12,
wherein the input phase shifter is between the first conversion circuit and the second conversion circuit,
wherein the first drive stage amplifier is between the input phase shifter and the first conversion circuit, and
wherein the second drive stage amplifier is between the input phase shifter and the second conversion circuit.

14. The power amplification device according to claim 11,
wherein the input phase shifter comprises a transmission line of the substrate, and
wherein in the chip device, the first drive stage amplifier, the first conversion circuit, the second drive stage amplifier, and the second conversion circuit are in sequence in the second direction.

15. The power amplification device according to claim 10, wherein the first differential amplifier and the second differential amplifier are between the first conversion circuit and the second conversion circuit.

16. The power amplification device according to claim 15, wherein the input phase shifter comprises a hybrid coupler.

17. The power amplification device according to claim 15, wherein the input phase shifter comprises a transmission line of the substrate.

18. The power amplification device according to claim 15, wherein the input phase shifter comprises a transmission line of the chip device.
